(19) United States
(12) Patent Application Publication
(10) Pub. No.: US 2023/0028670 A1
(43) Pub. Date: Jan. 26, 2023

(54) METHOD OF MANUFACTURING MULTI-COMPONENT SEMICONDUCTOR NANOCRYSTAL, MULTI-COMPONENT SEMICONDUCTOR NANOCRYSTAL, AND QUANTUM DOT INCLUDING THE SAME

(71) Applicant: Samsung Display Co., Ltd., Yongin-si (KR)

(72) Inventors: Baekhee Lee, Yongin-si (KR); Jaejin Lyu, Yongin-si (KR); Junwoo Lee, Yongin-si (KR); Taekjoon Lee, Yongin-si (KR)

(21) Appl. No.: 17/812,150

(22) Filed: Jul. 12, 2022

(30) Foreign Application Priority Data
Jul. 16, 2021 (KR) 10-2021-0093737

(51) Int. Cl. C09K 11/88; C09K 11/08; C09K 11/02; B01J 19/12; B01J 19/06

(52) U.S. Cl. CPC C09K 11/883; C09K 11/0883; C09K 11/025; B01J 19/126; B01J 19/06; B82Y 20/00

(57) ABSTRACT

Provided are a method of manufacturing a multi-component semiconductor nanocrystal, a multi-component semiconductor nanocrystal manufactured by the method, and a quantum dot including the same. The method includes irradiating microwaves to a semiconductor nanocrystal synthesis composition, and the semiconductor nanocrystal synthesis composition includes a precursor including a Group I element, a precursor including a Group II element, a precursor including a Group III element, a precursor including a Group V element, a precursor including a Group VI element, or any combination thereof.

### CROSS-REFERENCE TO RELATED APPLICATION

This application claims priority to and the benefit of Korean Patent Application No. 10-2021-0093737, filed on Jul. 16, 2021, in the Korean Intellectual Property Office, the entire content of which is hereby incorporated by reference in its entirety.

### BACKGROUND

### 1. Field

One or more embodiments of the present disclosure relate to a method of manufacturing a multi-component semiconductor nanocrystal, a multi-component semiconductor nanocrystal, and a quantum dot including the same.

### 2. Description of the Related Art

A quantum dot is a nanocrystal of a semiconductor material and exhibits a quantum confinement effect. When the quantum dot receives light from an excitation source and reaches an energy excited state, the quantum dot emits energy according to its corresponding energy bandgap. Even in the case of the same material, the wavelength thereof varies depending on the particle size thereof. Therefore, a size of a quantum dot may be controlled to allow light in a desired wavelength band to be obtained and characteristics such as excellent color purity and high luminescence efficiency to be exhibited. Due to this, the quantum dot may be applied to various elements and/or devices.

### SUMMARY

One or more embodiments include a method of manufacturing a multi-component semiconductor nanocrystal, capable of mass-producing multi-component semiconductor nanocrystals having excellent and uniform (e.g., substantially uniform) quality with high yield by using microwaves. In addition, one or more embodiments include a multi-component semiconductor nanocrystal manufactured by the aforementioned method and a quantum dot including the same.

Additional aspects of embodiments will be set forth in part in the description which follows and, in part, will be apparent from the description, or may be learned by practice of the presented embodiments of the disclosure.

According to one or more embodiments, a method of manufacturing a multi-component semiconductor nanocrystal includes irradiating microwaves to a semiconductor nanocrystal synthesis composition, wherein the semiconductor nanocrystal synthesis composition includes a precursor including a Group I element, a precursor including a Group II element, a precursor including a Group III element, a precursor including a Group V element, a precursor including a Group VI element, or any combination thereof.

According to one or more embodiments, there is provided a multi-component semiconductor nanocrystal manufactured by the aforementioned method.

According to one or more embodiments, there is provided a quantum dot including the multi-component semiconductor nanocrystal.

### BRIEF DESCRIPTION OF THE DRAWINGS

The above and other aspects and features of certain embodiments of the disclosure will be more apparent from the following description taken in conjunction with the accompanying drawings, in which:

FIG. 1 illustrates a method of manufacturing a multi-component semiconductor nanocrystal, according to an embodiment; and

FIG. 2 illustrates absorbance and photoluminescence (PL) spectra of semiconductor nanocrystals.

### DETAILED DESCRIPTION

Reference will now be made in more detail to embodiments of the present disclosure, examples of which are illustrated in the accompanying drawings, wherein like reference numerals refer to like elements throughout. In this regard, the present embodiments may have different forms and should not be construed as being limited to the descriptions set forth herein. Accordingly, certain embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in more detail in the written description. Effects and features of the subject matter of the disclosure, and methods of achieving them will be clarified with reference to embodiments described below in more detail with reference to the drawings. However, the subject matter of the disclosure is not limited to the following embodiments and may be embodied in various forms.

It will be understood that although the terms “first,” “second,” etc. may be used herein to describe various elements, these elements should not be limited by these terms. These terms are only used to distinguish one element from another.

The singular forms “a,” “an,” and “the” as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements. For example, unless otherwise limited, the terms “include” and/or “comprise” may mean both the case of consisting of only the features or elements described in the specification and the case of further including other elements.

In the present specification, the term “Group I” may include Group IA elements and Group IB elements in the International Union of Pure and Applied Chemistry (IUPAC) Periodic Table, and examples of Group I elements may include Cu, Ag, Au, and Rg. However, the disclosure is not limited thereto.

In the present specification, the term “Group II” may include Group IIA elements and Group IIB elements in the IUPAC Periodic Table, and examples of Group II elements may include Zn, Cd, Hg, and Cn. However, the disclosure is not limited thereto.

In the present specification, the term “Group III” may include Group IIIA elements and group IIIB elements in the IUPAC Periodic Table, and examples of Group III elements may include Al, In, Ga, Ti, and Nh. However, the disclosure is not limited thereto.

In this specification, the term “Group V” may include Group VA elements and Group VB elements in the IUPAC Periodic Table, and examples of Group V elements may include N, P, and As. However, the disclosure is not limited thereto.

In the present specification, the term “Group VI” may include Group VIA elements and group VIB elements in the IUPAC Periodic Table, and examples of Group VI elements may include O, S, Se, and Te. However, the disclosure is not limited thereto.

In the present specification, “quantum yield” and “luminescence efficiency” may be used interchangeably as having substantially the same meaning.

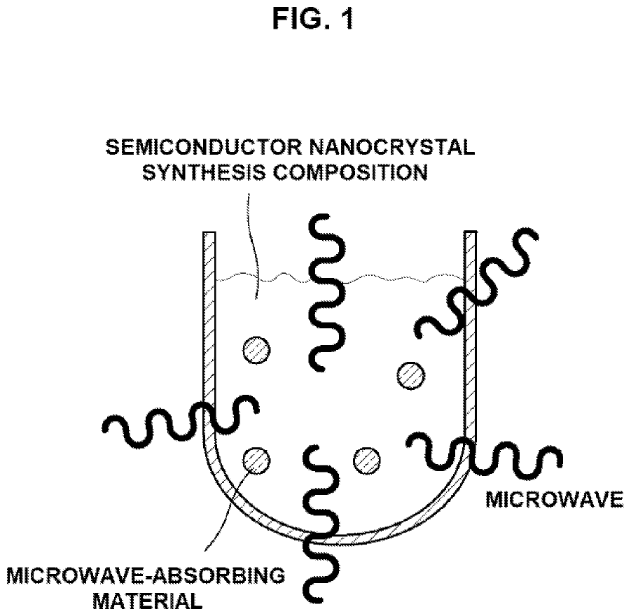

Hereinafter, a method of manufacturing a multi-component semiconductor nanocrystal, according to an embodiment, will be described with reference to FIG. 1.

The method of manufacturing the multi-component semiconductor nanocrystal, according to an embodiment, includes irradiating microwaves to a semiconductor nanocrystal synthesis composition.

A semiconductor nanocrystal synthesis method has used a cation exchange reaction of precursors in a colloidal solution. In this case, it was difficult to achieve high quantum yield because the synthesis was not easy. In addition, in the case of an alloy including an element having a high diffusion temperature, a high temperature environment of 400° C. or higher was utilized for a cation exchange reaction. However, because a use temperature of a solvent is less than 340° C., two-component alloys are mainly formed instead of desired three-component alloys (or alloys including more than three components).

Because the method of manufacturing the multi-component semiconductor nanocrystal, according to an embodiment, performs heating and pressurization by using microwaves, the heating rate is fast and the yield is high, thereby enabling mass production.

According to an embodiment, the method of manufacturing the multi-component semiconductor nanocrystal may be performed by one step of irradiating microwaves to the semiconductor nanocrystal synthesis composition. Therefore, the use of embodiments of the aforementioned method may simplify a process, facilitate mass production, and increase productivity.

The semiconductor nanocrystal synthesis composition includes a precursor including a Group I element, a precursor including a Group II element, a precursor including a Group III element, a precursor including a Group V element, a precursor including a Group VI element, or any combination thereof.

According to an embodiment, the multi-component semiconductor nanocrystal may include two or more elements.

For example, the multi-component semiconductor nanocrystal may be a two-component compound including two elements, a three-component compound including three elements, or a four-component compound including four elements.

According to an embodiment, the semiconductor nanocrystal synthesis composition may include three or more elements that are different from each other.

According to an embodiment, the precursor included in the semiconductor nanocrystal synthesis composition may include a precursor including a Group I element, a precursor including a Group II element, or any combination thereof, and may optionally further include a precursor including a Group III element, a precursor including a Group V element, a precursor including a Group VI element, or any combination thereof.

According to an embodiment, the Group I element may include Cu, Ag, and/or Au.

According to an embodiment, the Group II element may include Zn, Cd, and/or Hg.

According to an embodiment, the Group III element may include Al, Ga, In, and/or Ti.

According to an embodiment, the Group V element may include N, P, and/or As.

According to an embodiment, the Group VI element may include S, Se, and/or Te.

According to an embodiment, the precursor including the Group I element may include copper and/or a copper compound, silver and/or a silver compound, and/or gold and/or a gold compound.

For example, the precursor including the Group I element may include copper acetate, copper bromide, copper chloride, copper iodide, copper acetylacetonate, copper stearate, silver acetate, silver bromide, silver chloride, silver iodide, silver acetylacetonate, silver nitrate, silver stearate, gold chloride trihydrate (HAuCl₄.3H₂O), and/or the like.

According to an embodiment, the precursor including the Group II element may include zinc and/or a zinc compound, cadmium and/or a cadmium compound, and/or mercury and/or a mercury compound.

For example, the precursor including the Group II element may include zinc acetate, dimethyl zinc, diethyl zinc, zinc carboxylate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, cadmium oxide, dimethyl cadmium, diethyl cadmium, cadmium carbonate, cadmium acetate dihydrate, cadmium acetylacetonate, cadmium fluoride, cadmium chloride, cadmium iodide, cadmium bromide, cadmium perchlorate, cadmium phosphide, cadmium nitrate, cadmium sulfate, cadmium carboxylate, mercury iodide, mercury bromide, mercury fluoride, mercury cyanide, mercury nitrate, mercury perchlorate, mercury sulfate, mercury oxide, mercury carbonate, mercury carboxylate, and/or the like.

According to an embodiment, the precursor including the Group III element may include aluminum and/or an aluminum compound, gallium and/or a gallium compound, indium and/or an indium compound, and/or thallium and/or a thallium compound.

For example, the precursor including the Group III element may include aluminum phosphate, aluminum acetylacetonate, aluminum chloride, aluminum fluoride, aluminum oxide, aluminum nitrate, aluminum sulfate, gallium acetylacetonate, gallium chloride, gallium fluoride, gallium oxide, gallium nitrate, gallium sulfate, gallium acetate, indium acetate, indium chloride, indium oxide, indium nitrate, indium sulfate, indium carboxylate, and/or the like.

According to an embodiment, the precursor including the Group V element may include nitrogen and/or a nitrogen compound, phosphorus and/or a phosphorus compound, and/or arsenic and/or an arsenic compound.

For example, the precursor including the Group V element may include alkylphosphine, tris(trialkylsilyl)phosphine, tris(dialkylsilyl)phosphine, tris(dialkylamino)phosphine, tris(trimethylsilyl)phosphine, arsenic oxide, arsenic chloride, arsenic sulfate, arsenic bromide, arsenic iodide, nitric oxide, nitric acid, ammonium nitrate, and/or the like.

According to an embodiment, the precursor including the Group VI element may include sulfur and/or a sulfur compound, selenium and/or a selenium compound, and/or tellurium and/or a tellurium compound.

For example, the precursor including the Group VI element may include sulfur, trialkylphosphine sulfide, trialkenylphosphine sulfide, alkylaminosulfide, alkenylaminosulfide, alkylthiol, selenium, trialkylphosphine selenide, trialkenylphosphine selenide, alkylaminoselenide, alkenylaminoselenide, trialkylphosphinetelluride, trialkenylphosphinetelluride, alkylaminotelluride, alkenylaminotelluride, and/or the like.

According to an embodiment, the semiconductor nanocrystal synthesis composition may include a microwave-absorbing material.

According to an embodiment, the microwave-absorbing material may have a diameter (e.g., an average particle diameter) of about 10 μm to about 10 mm.

According to an embodiment, the microwave-absorbing material may include a high dielectric constant material such as, for example, perovskite, ferrite (e.g., NiFeO), hexagonal ferrite (e.g., BaFeO), iron oxide, and/or silicon carbide (SiC).

Because the microwave-absorbing material is included, the energy of the microwaves irradiated to the semiconductor nanocrystal synthesis composition may be transferred more efficiently, and thus, mass synthesis may be enabled and productivity may be increased. In addition, the type (e.g., kind or composition) and size of the microwave-absorbing material may be controlled so that the heating rate of the semiconductor nanocrystal synthesis composition increases by several tens of times or more, and the heating rate may be controlled so that the characteristics of semiconductor nanocrystals are improved.

According to an embodiment, the semiconductor nanocrystal synthesis composition may further include a ligand and a solvent. The ligand may be bonded to a metal atom of any of the precursors described herein.

According to an embodiment, the ligand may include a C₄-C₃₀ fatty acid.

For example, the ligand may include palmitic acid, palm itoleic acid, stearic acid, oleic acid, trioctylphosphine, trioctylphosphine oxide, oleylamine, octylamine, trioctylamine, hexadecylamine, octanethiol, dodecanethiol, hexylphosphonic acid, tetradecylphosphonic acid, octylphosphonic acid, and/or the like.

According to an embodiment, the solvent included in the semiconductor nanocrystal synthesis composition may include an organic solvent. For example, the solvent may include 1-octadecene (ODE), trioctylamine (TOA), trioctylphosphine (TOP), oleylamine, or any combination thereof.

According to an embodiment, the semiconductor nanocrystal synthesis composition may further include an ionic liquid.

The ionic liquid may include a compound containing an organic cation and an organic anion, and/or an organic cation and an inorganic anion. Unlike solid salts, the sizes of the cation and the anion are relatively large. Accordingly, their lattice energy is low and thus a melting point is low.

For example, the ionic liquid may include 1,3-dialkylimidazolium, N-alkylpyridinium, tetraalkylammonium, tetraalkylphosphonium, and/or N-alkylpyrrolidinium as the cation, and may include bis(trifluoromethylsulfonyl)imide, tetrafluoroborate, hexafluorophosphate, trifluoromethanesulfonate, chloride, bromide, iodide, nitrate, and/or acetate as the anion.

According to an embodiment, the ionic liquid may have a loss tangent of about 0.2 to about 2.

When the semiconductor nanocrystal synthesis composition includes the ionic liquid, the pressure of the semiconductor nanocrystal synthesis composition may be increased. Therefore, the productivity of the manufacture of the multi-component semiconductor nanocrystal may be further improved by using a high pressure condition.

According to an embodiment, the semiconductor nanocrystal synthesis composition may further include an additive.

According to an embodiment, the additive may include a compound represented by Formula 10 below:

A⁺X⁻. Formula 10

In Formula 10,

A⁺ is a hydrogen cation (H⁺) or a monovalent cation of a metal, and

X⁻ is a halide ion.

For example, the additive may include ZnCl and/or HF.

According to an embodiment, the semiconductor nanocrystal synthesis composition may be heated and pressurized by the irradiated microwaves.

For example, the output of the microwaves may be about 100 W to about 600 W, for example, about 100 W to about 500 W, or about 100 W to about 400 W.

According to an embodiment, the maximum temperature of the semiconductor nanocrystal synthesis composition heated by the irradiated microwaves may be about 100° C. to about 350° C., for example, about 100° C. to about 320° C.

According to an embodiment, the maximum pressure of the semiconductor nanocrystal synthesis composition pressurized by the irradiated microwaves may be about 1 atm to about 100 atm, for example, about 1 atm to about 50 atm, or about 1 atm to about 25 atm.

According to an embodiment, the irradiating of the microwaves to the semiconductor nanocrystal synthesis composition may be performed in or by a magnetic synthesizer.

According to an embodiment, the multi-component semiconductor nanocrystal may include a Group II-VI semiconductor nanocrystal, a Group III-V semiconductor nanocrystal, a Group I-III-VI semiconductor nanocrystal, a Group I-V-VI semiconductor nanocrystal, a Group II-III-VI semiconductor nanocrystal, or any combination thereof.

According to an embodiment, the multi-component semiconductor nanocrystal may include three or more elements that are different from each other. For example, the multi-component semiconductor nanocrystal may include two or more cation elements and one or more anion elements.

Examples of the Group II-VI semiconductor nanocrystal may include a binary compound such as CdS, CdSe, CdTe, ZnS, ZnSe, ZnTe, ZnO, HgS, HgSe, HgTe, MgSe, and/or MgS, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, HgZnS, HgZnSe, and/or HgZnTe, a quaternary compound such as CdZnSeS, CdZnSeTe, CdZnSTe, CdHgSeS, CdHgSeTe, CdHgSTe, CdHgZnTe, HgZnSeS, HgZnSeTe, and/or HgZnSTe, or any combination thereof.

Examples of the Group III-V semiconductor nanocrystal may include a binary compound such as GaN, GaP, GaAs, GaSb, AlN, AlP, AlAs, AlSb, InN, InP, InAs, and/or InSb, a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb, a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb, or any combination thereof. On the other hand, the Group III-V semiconductor nanocrystal may further include a Group II element. Examples of the Group III-V semiconductor nanocrystal that further includes the Group II element may include InZnP, InGaZnP, InAlZnP, and/or the like.

Examples of the Group semiconductor nanocrystal may include a ternary compound such as AgInS, AgInS₂, CuInS, CuInS2, CuGaO₂, AgGaO₂, and/or AgAlO₂, or any combination thereof.

Examples of the Group I-V-VI semiconductor nanocrystal may include a ternary compound such as CuPS, CuPSe, CuPTe, CuAsS, CuAsSe, CuAsTe, AgPS, AgPSe, AgPTe, AgAsS, AgAsSe, AgAsTe, AuPS, AuPSe, AuPTe, AuAsS, AuAsSe, and/or AuAsTe, or any combination thereof.

Examples of the Group semiconductor nanocrystal may include a ternary compound such as CdGaS, CdGaSe, CdGa₂Se₃, CdGaTe, CdInS, CdInSe, CdIn₂S₃, CdIn₂Se₃, CdInTe, ZnGaS, ZnGaSe, ZnGa₂Se₃, ZnGaTe, ZnInS, ZnInSe, ZnIn₂S₃, ZnIn₂Se₃, ZnInTe, HgGaS, HgGaSe, HgGa₂Se₃, HgGaTe, HgInS, HgInSe, HgIn₂S₃, HgIn₂Se₃, and/or HgInTe, a quaternary compound such as CdInGaS₃, CdInGaSe₃, ZnInGaS₃, ZnInGaSe₃, HgInGaS₃, and/or HgInGaSe₃, or any combination thereof.

At this time, the binary compound, the ternary compound, and/or the quaternary compound may exist in particles at a uniform (e.g., substantially uniform) concentration, and/or may exist in the same particle as the concentration distribution is partially divided into different states from each other. For example, embodiments of the present disclosure may produce particles respectively consisting of the binary compound, the ternary compound, or the quaternary compound, and/or embodiments of the present disclosure may produce particles that include one or more selected from the binary compound, the ternary compound, and the quaternary compound at the same or different concentration levels.

The multi-component semiconductor nanocrystal may have an emission wavelength of about 1 nm to about 10 mm. For example, the multi-component semiconductor nanocrystal may emit ultraviolet (UV) light, visible light, and/or infrared (IR) light.

According to an aspect of some embodiments, there is provided a multi-component semiconductor nanocrystal manufactured by the method of manufacturing the multi-component semiconductor nanocrystal.

According to an aspect of some embodiments, there is provided a quantum dot including the multi-component semiconductor nanocrystal.

According to an embodiment, the quantum dot may include a core and a shell on the core. The core may include the multi-component semiconductor nanocrystal.

According to an embodiment, the core may have a radius of about 0.1 nm to about 5 nm, or about 0.5 nm to about 2.5 nm, for example, about 0.6 nm to about 2.4 nm, about 0.75 nm to about 2.25 nm, or about 1 nm to about 2 nm.

According to an embodiment, the shell may include one or more layers. For example, the quantum dot may include a core and a first shell layer outside the core, may include a core, a first shell layer, and a second shell layer outside the first shell layer, or may include a core, a first shell layer, a second shell layer, and a third shell layer outside the second shell layer. In some embodiments, the shell of the quantum dot may include four or more layers.

The shell of the quantum dot may act as a protective layer to prevent or reduce chemical denaturation of the core and maintain semiconductor properties, and/or may act as a charging layer to impart electrophoretic properties to the quantum dot.

According to an embodiment, the shell may have a thickness of about 0.1 nm to about 10 nm, for example, about 0.5 nm to about 5 nm, about 0.7 nm to about 3 nm, about 1 nm to about 2 nm, or about 1.2 nm to about 1.5 nm.

The quantum dot may emit visible light other than blue light. For example, the quantum dot may emit light having a maximum emission wavelength of about 500 nm to about 750 m. Therefore, the quantum dot may be designed to emit wavelengths of light of various suitable color ranges.

According to an embodiment, the quantum dot may emit green light having a maximum emission wavelength of about 500 nm to about 750 nm. According to another embodiment, the quantum dot may emit red light having a maximum emission wavelength of about 600 nm to about 750 nm.

According to an embodiment, the quantum dot may have a diameter (e.g., an average particle diameter) of about 1 nm to about 20 nm. For example, the quantum dot may have a diameter of about 3 nm to about 15 nm, for example, about 4 nm to about 12 nm, about 5 nm to about 10 nm, or about 6 nm to about 9 nm.

According to an embodiment, the quantum dot may have a diameter (e.g., an average particle diameter) of about 4 nm to about 6 nm, and may emit green light.

According to an embodiment, the quantum dot may have a diameter (e.g., an average particle diameter) of about 7 nm to about 9 nm, and may emit red light.

According to an embodiment, the quantum dot may have a full width at half maximum (FWHM) of about 60 nm or less, for example, about 55 nm or less, or about 40 nm or less, in an emission wavelength spectrum. When the FWHM of the quantum dot satisfies the above range, color purity and color reproducibility may be excellent and a wide viewing angle may be improved.

According to an embodiment, the form of the quantum dot is not particularly limited, and may be any suitable form generally used in the art. For example, the quantum dot may have the form of spherical, pyramidal, multi-arm, or cubic nanoparticles, nanotubes, nanowires, nanofibers, nanoplatelet particles, or the like.

According to an embodiment, the shell may include a Group II-VI compound, a Group III-V compound, or any combination thereof.

According to an embodiment, the shell may further include a metal and/or non-metal oxide, a semiconductor compound, or any combination thereof.

For example, the metal and/or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄.

Also, for example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like.

According to an embodiment, the shell may have a bandgap energy greater than that of the core.

According to an embodiment, the quantum dot may further include, in addition to the above-described composition, other compounds.

For example, the quantum dot may further include, in the core and/or the shell, the Group II-VI compound, the Group III-VI compound, the Group III-V compound, the Group IV-VI compound, the Group IV element or compound, the Group compound, or any combination thereof, which is described above.

Hereinafter, the multi-component semiconductor nanocrystal, the quantum dot including the same, and the manufacturing method thereof, according to embodiments, will be described in more detail with reference to Examples.

### Examples

### Synthesis Example 1: Manufacture of InGaP Semiconductor Nanocrystal, InGaP/ZnSe Semiconductor Nanocrystal, and InGaP/ZnSe/ZnS Semiconductor Nanocrystal

Indium acetate (10 mmol), zinc acetate (10 mmol), gallium acetylacetonate (8 mmol), and palmitic acid (70 mmol) were dissolved in a solvent of 1-octadecene (50 mL) to prepare a cation precursor. Tris(trimethylsilyl)phosphine and trioctylphosphine were mixed to prepare an anion precursor. After the cation precursor was mixed with the anion precursor, microwaves were irradiated thereto with 400 W and a temperature was maintained at 300° C. to manufacture an InGaP semiconductor nanocrystal.

The manufactured InGaP semiconductor nanocrystal was used as the core and ZnSe and ZnS were sequentially synthesized on the surface thereof by using a hot injection synthesis method using an existing 3-neck round bottom flask to synthesize a semiconductor nanocrystal having a core/shell structure of InGaP/ZnSe or a semiconductor nanocrystal having a core/shell/shell structure of InGaP/ZnSe/ZnS or InGaP/ZnSeS/ZnS.

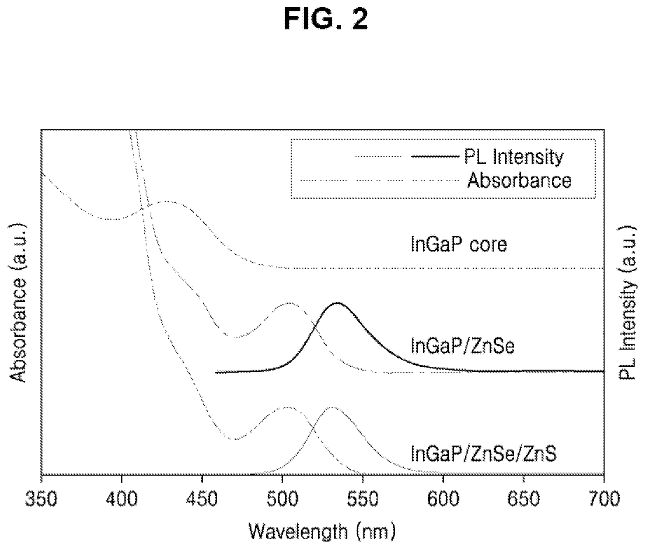

Absorbance and photoluminescence (PL) spectra of the InGaP semiconductor nanocrystal, the InGaP/ZnSe semiconductor nanocrystal, and the InGaP/ZnSe/ZnS semiconductor nanocrystal, which were manufactured in Synthesis Example 1, were measured by using UV-VIS and PL spectrometer. The results thereof are shown in FIG. 2, and the synthesis was confirmed. As the measurement equipment, Quantum Efficiency Measurement System QE-2100 available from Otsuka was used.

### Evaluation Example 1: Evaluation of Characteristics of Semiconductor Nanocrystals

The maximum emission wavelength, FWHM, and quantum yield of the semiconductor nanocrystals manufactured in Synthesis Example 1 were evaluated from the PL spectra by using Quantum Efficiency Measurement System QE-2100 available from Otsuka. The results thereof are shown in Table 1.

TABLE 1

| | Maximum | | |
|---|---|---|---|
| | emission | | |
| | wavelength | FWHM | Quantum |
| | (nm) | (nm) | yield (%) |
| InGaP/ZnSe/ZnS | 530 | 40 | 94 |
| InGaP/ZnSeS/ZnS | 525 | 40 | 92 |

Referring to Table 1, it can be seen that the multi-component semiconductor nanocrystal manufactured by the method according to the embodiment has a narrow FWHM and excellent quantum yield.

Because the method of manufacturing the multi-component semiconductor nanocrystal uses microwaves, the heating rate is fast and the yield is high, thereby enabling mass production. In addition, the multi-component semiconductor nanocrystal manufactured by the aforementioned method has uniform (e.g., substantially uniform) quality, and the quantum dot including the same have high efficiency and high absorbance.

It should be understood that the embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims, and equivalents thereof.

What is claimed is:

1. A method of manufacturing a multi-component semiconductor nanocrystal, the method comprising irradiating microwaves to a semiconductor nanocrystal synthesis composition,
wherein the semiconductor nanocrystal synthesis composition comprises a precursor comprising a Group I element, a precursor comprising a Group II element, a precursor comprising a Group III element, a precursor comprising a Group V element, a precursor comprising a Group VI element, or any combination thereof.

2. The method of claim 1, wherein the semiconductor nanocrystal synthesis composition comprises three or more elements that are different from each other.

3. The method of claim 1, wherein the semiconductor nanocrystal synthesis composition comprises the precursor comprising the Group I element, the precursor comprising the Group II element, or any combination thereof, and optionally further comprises the precursor comprising the Group III element, the precursor comprising the Group V element, the precursor comprising the Group VI element, or any combination thereof.

4. The method of claim 1, wherein the multi-component semiconductor nanocrystal comprises a Group II-VI semiconductor nanocrystal, a Group III-V semiconductor nanocrystal, a Group I-III-VI semiconductor nanocrystal, a Group I-V-VI semiconductor nanocrystal, a Group II-Ill-VI semiconductor nanocrystal, or any combination thereof.

5. The method of claim 1, wherein the semiconductor nanocrystal synthesis composition further comprises a microwave-absorbing material.

6. The method of claim 5, wherein the microwave-absorbing material comprises perovskite, ferrite, hexagonal ferrite, iron oxide, and/or silicon carbide (SiC).

7. The method of claim 1, wherein the semiconductor nanocrystal synthesis composition further comprises a ligand and a solvent.

8. The method of claim 7, wherein the ligand comprises a C₄-C₃₀ fatty acid.

9. The method of claim 7, wherein the solvent comprises 1-octadecene (ODE), trioctylamine (TOA), trioctylphosphine (TOP), or any combination thereof.

10. The method of claim 1, wherein the semiconductor nanocrystal synthesis composition further comprises an ionic liquid, and
the ionic liquid has a loss tangent of about 0.2 to about 2.

11. The method of claim 1, wherein the semiconductor nanocrystal synthesis composition further comprises an additive, and
the additive comprises a compound represented by Formula 10 below:
A⁺X⁻, Formula 10
wherein, in Formula 10,
A⁺ is a hydrogen cation (H⁺) or a monovalent cation of a metal, and
X⁻ is a halide ion.

12. The method of claim 1, wherein the semiconductor nanocrystal synthesis composition is heated and pressurized by the irradiated microwaves.

13. The method of claim 12, wherein a maximum temperature of the semiconductor nanocrystal synthesis composition heated by the irradiated microwaves is about 100° C. to about 350° C.

14. The method of claim 1, wherein the irradiating of the microwaves to the semiconductor nanocrystal synthesis composition is performed in a magnetic synthesizer.

15. The method of claim 1, wherein the method of manufacturing the multi-component semiconductor nanocrystal is performed by one step of irradiating the microwaves to the semiconductor nanocrystal synthesis composition.

16. The multi-component semiconductor nanocrystal manufactured by the method of claim 1.

17. A quantum dot comprising the multi-component semiconductor nanocrystal of claim 16.

18. The quantum dot of claim 17, wherein the quantum dot comprises a core and a shell on the core,
the core comprises the multi-component semiconductor nanocrystal, and
the shell comprises one or more layers.

19. The quantum dot of claim 18, wherein the shell comprises a Group II-VI compound, a Group III-V compound, or any combination thereof.

20. The quantum dot of claim 18, wherein the shell has a bandgap energy greater than that of the core.
